(19) United States
(12) Patent Application Publication
(10) Pub. No.: US 2022/0080783 A1
(43) Pub. Date: Mar. 17, 2022

(54) PIEZOELECTRIC TIRE

(71) Applicant: Sumitomo Rubber Industries, Ltd., Kobe-shi (JP)

(72) Inventors: Akiyoshi TAMANO, Kobe-shi (JP); Yuuji UMINO, Fukushima-shi (JP); Akihiro KANAZAWA, Fukushima-shi (JP); Takuya KUWATA, Fukushima-shi (JP)

(73) Assignee: Sumitomo Rubber Industries, Ltd., Kobe-shi (JP)

(21) Appl. No.: 17/474,064

(22) Filed: Sep. 14, 2021

(30) Foreign Application Priority Data
Sep. 14, 2020 (JP) 2020-153512

(51) Int. Cl. B60C 19/00; H01L 41/08; H01L 41/04; H01L 41/113

(52) U.S. Cl. CPC B60C 19/00; H01L 41/0805; H01L 41/047; H01L 41/113; H01L 41/042

(57) ABSTRACT

A piezoelectric tire can include a tire body, a coating type piezoelectric portion, and a circuit unit. The coating type piezoelectric portion can be coated on the tire body and can generate electric power corresponding to strain generated in a ground-contact surface of the tire body. The circuit unit can be provided to the tire body and can be driven by the electric power generated by the coating type piezoelectric portion. Since a coating type is used as the piezoelectric portion, the piezoelectric portion can be in close contact with the tire body.

### CROSS-REFERENCE TO RELATED APPLICATION

The present application claims priority to Japanese patent application JP 2020-153512, filed on Sep. 14, 2020, the entire contents of which are incorporated herein by reference in its entirety.

### BACKGROUND

### Field

Embodiments of the present disclosure related to a piezoelectric tire to generate electric power corresponding to strain of a ground-contact surface of the tire.

### Description of the Background Art

For example, Japanese Laid-Open Patent Publication No. 2006-223054 describes a tire including a power generation device. The power generation device includes a plurality of power generation elements and a capacitor. Each power generation element includes two elastic electrodes and an elastic polymer compound (dielectric elastomer) interposed between the electrodes. The elastic polymer compound generates a potential difference between the electrodes on the basis of strain generated in the tire. The capacitor stores the electrical energy generated in the power generation element. The plurality of power generation elements are provided at at least one side surface inside the tire on a circumference centered on the rotation axis of the tire. The length in the circumferential direction of each power generation element is set such that strain due to compression caused by the rotating tire coming into the ground and strain due to expansion are not applied to the power generation element at the same time.

In Japanese Laid-Open Patent Publication No. 2006-223054, the two electrodes included in each piezoelectric element (power generation element) are formed by bonding to both surfaces of the dielectric elastomer or by sputtering or vapor deposition. However, the electrodes formed by such a method may have a problem about durability. This is because, during running of a vehicle, relatively large tire strain is repeated at a high cycle, and the electrodes may easily peel off or crack due to such a harsh usage condition specific to the tire.

Embodiments of the present disclosure have been made in view of the above circumstances (and other circumstances), and an object of the present disclosure, among multiple objects, can be to suppress peeling and/or cracking of electrodes included in a piezoelectric element, for instance, to improve the durability of a piezoelectric tire.

### SUMMARY

According to an aspect a piezoelectric tire is disclosed or provided. The piezoelectric tire can comprise a tire body; a coating piezoelectric portion coated on the tire body to generate electric power corresponding to strain generated in a ground-contact surface of the tire body; and circuitry provided to the tire body and configured to be driven by the electric power generated by the coating type piezoelectric portion.

According to another aspect, a tire system is disclosed or provided. The tire system can comprise a coating piezoelectric portion coated on a tire body to generate electric power corresponding to strain generated in a ground-contact surface of the tire body; and circuitry provided relative to the tire body and configured to be driven by the electric power generated by the coating type piezoelectric portion.

### BRIEF DESCRIPTION OF THE DRAWINGS

FIG. 1 is a schematic diagram of a piezoelectric tire according to a first embodiment of the present disclosure;

FIG. 2 is a cross-sectional view of the piezoelectric tire of FIG. 1;

FIG. 3 is a diagram illustrating electromotive force in a piezoelectric portion according to one or more embodiments of the present disclosure;

FIG. 4 is a characteristic diagram of FEM analysis in the width direction of a tire including according to one or more embodiments of the present disclosure;

FIG. 5 is a diagram showing output voltage data at the time of rotation of a tire including according to one or more embodiments of the present disclosure;

FIG. 6 is a block diagram of a circuit unit according to one or more embodiments of the present disclosure;

FIG. 7 is a schematic diagram of a piezoelectric tire according to a second embodiment of the present disclosure;

FIG. 8 is an arrangement diagram of a plurality of piezoelectric portions according to one or more embodiments of the present disclosure;

FIG. 9 is an arrangement diagram of a plurality of piezoelectric portions according to a first modification according to one or more embodiments of the present disclosure; and

FIG. 10 is an arrangement diagram of a plurality of piezoelectric portions according to a second modification according to one or more embodiments of the present disclosure according to one or more embodiments of the present disclosure.

### DETAILED DESCRIPTION

In order to solve the above problem described in the background section (and other problem(s)), embodiments of the present disclosure can provide a piezoelectric tire that can include a tire body, a coating piezoelectric portion, and a circuit unit. The circuit unit may be implemented in circuitry (e.g., one or more circuit portions). The coating piezoelectric portion can be coated on the tire body and can generate electric power corresponding to strain generated in a ground-contact surface of the tire body. The circuitry can be provided relative to the tire body (e.g., on or adjacent to) and driven by the electric power generated by the coating piezoelectric portion.

In one or more embodiments of the present disclosure, the coating piezoelectric portion can be coated on a back surface of a ground-contact portion of the tire body. Optionally, a resin layer may be provided so as to be interposed between the coating piezoelectric portion and the tire body such that the coating piezoelectric portion is not in direct contact with the tire body. Moreover, a length in a width direction of the coating piezoelectric portion can be not less than 70% and/or not greater than 150% of a ground-contact width under a maximum load in a standard of the Japan Automobile Tyre Manufacturers Association, Inc. Additionally or alternatively, a length in a circumferential direction of the coating piezoelectric portion can be not less than 40% and/or not greater than 90% of a ground-contact length under the maximum load in the standard of the Japan Automobile Tyre Manufacturers Association, Inc.

In one or more embodiments of the present disclosure, a plurality of the coating piezoelectric portions may be provided at different positions in at least either one of a circumferential direction and a width direction of the tire body. In this case, the plurality of the coating piezoelectric portions may have lengths different from each other in the circumferential direction, or may have lengths different from each other in the width direction. In addition, the plurality of the coating piezoelectric portions may each have a shape obtained by elongating a predetermined shape in at least either one of the circumferential direction and the width direction of the tire body.

In one or more embodiments of the present disclosure, the circuitry may include a wireless circuit configured to wirelessly transmit a signal of a sensor configured to detect a state of an object to be detected, to the outside, for instance, to outside the tire body, the tire, or a vehicle on which the tire is installed. In addition, the circuitry may include a power storage device configured to store the electric power generated by the coating piezoelectric portion and supply the stored electric power to the circuitry.

According to one or more embodiments of the present disclosure, since the coating can be used as the piezoelectric portion provided on the tire body, the piezoelectric portion can be in close contact with the tire body and flexibly follows strain of the tire body. Accordingly, peeling and/or cracking of electrodes included in the coating piezoelectric portion can be suppressed, for instance, so that the durability of the piezoelectric tire can be improved.

(First Embodiment)

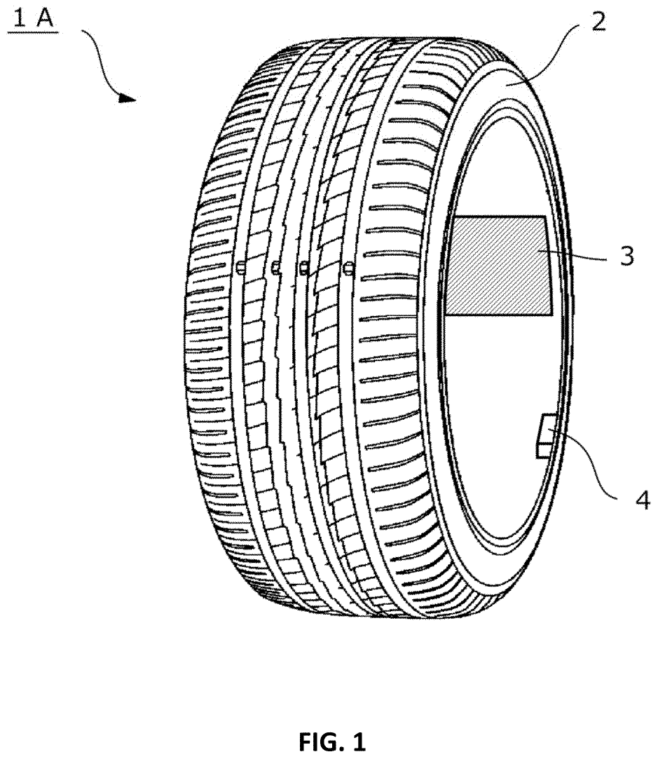

FIG. 1 is a schematic diagram of a piezoelectric tire according to a first embodiment of the present disclosure. The piezoelectric tire 1A can be mounted to an automobile, and can be widely applied to various vehicles such as motorcycles and bicycles, although the shape and size thereof may be different. Similar to a general tire, the piezoelectric tire 1A can be composed of a tire body 2, which can be formed of an elastic body such as rubber, and a piezoelectric portion 3 and circuitry 4 can be added to the tire body 2. In some respects the tire body 2, the piezoelectric portion 3, and the circuitry 4 may be referred to or characterized as a tire system.

The piezoelectric portion 3 can be provided on a back surface of a ground-contact portion of the tire body 2 and can generate electric power corresponding to strain generated in a ground-contact surface of the tire body 2. The ground-contact portion of the tire body 2 may have treads, etc. The piezoelectric portion 3 can include a pair of electrodes arranged on the upper side and the lower side and a piezoelectric film interposed between the electrodes. In the present embodiment, the piezoelectric portion 3 can be or include a piezoelectric portion coated on the inner surface of the tire body 2, that is, a coating type piezoelectric portion, can be used. Examples of the coating mode include silk printing, screen printing, inkjet printing, coating with a bar coater, and spray coating (see, for example, Japanese Laid-Open Patent Publication No. 2018-157950), and bonding, sputtering, and vapor deposition are excluded.

Specifically, the lower electrode can be coated on the inner surface of the tire body 2, and the piezoelectric film can be formed on the upper part of the lower electrode. As the piezoelectric film, a flexible resin-based piezoelectric material such as polyvinylidene chloride (PVDC), polylactic acid (PLA), polyvinylidene fluoride (PVDF), and a copolymer (P(VDF-TrFE)) of vinylidene fluoride (VDF) and trifluoroethylene (TrFE) can be used. The upper electrode can be formed on the upper part of the piezoelectric film, for instance, by using the same method as for the lower electrode.

Since a coating is used as the piezoelectric portion 3, the adhesion to the tire body 2 can be improved as compared with a non-coating type such as bonding, sputtering, and vapor deposition. Accordingly, peeling and/or cracking of the electrodes, which can be included in the piezoelectric portion 3, can be suppressed, while ensuring the followability of the electrodes to strain of the tire body 2.

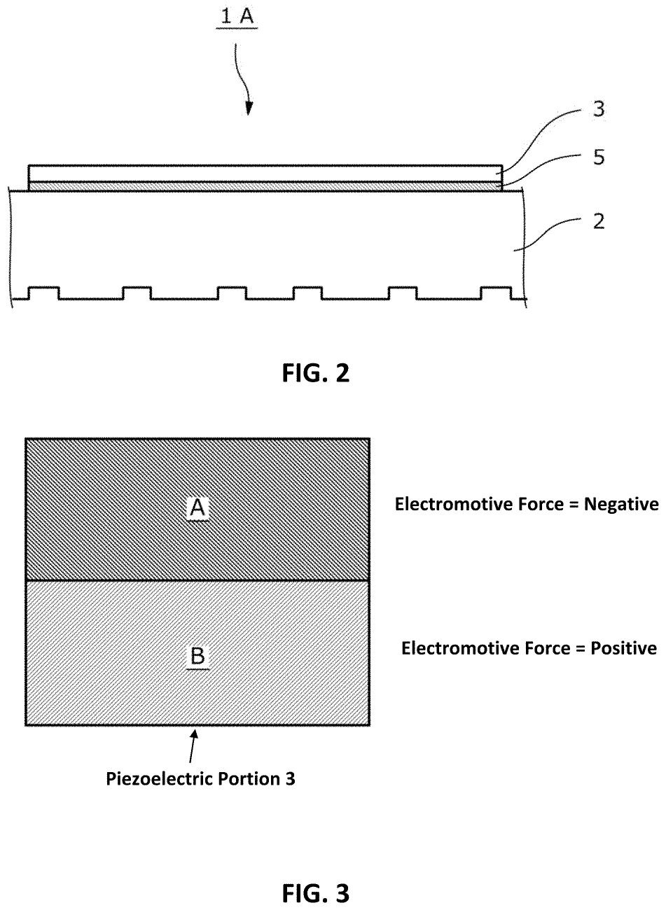

Moreover, as shown in FIG. 2, a resin layer 5 may be interposed between the piezoelectric portion 3 and the tire body 2. Generally, the tire body 2 can contain a sulfur component, and a phenomenon (bleed-out) that the sulfur component emerges on the surface of the tire body 2 due to aging, may occur. In the case where the piezoelectric portion 3 is in direct contact with the back surface of the tire body 2, the piezoelectric portion 3 may be damaged by the sulfur component that emerges on the surface of the tire body 2, which may cause deterioration or alteration of the piezoelectric portion 3. In order to solve this problem, the resin layer 5 can be interposed between the piezoelectric portion 3 and the tire body 2 as a protective layer to prevent the piezoelectric portion 3 from being in direct contact with the tire body 2. The resin layer 5 can be formed by coating such that the resin layer 5 is not easily peeled off from the tire body 2, and, moreover, may not contain a sulfur component.

FIG. 3 is a diagram illustrating electromotive force in the piezoelectric portion 3. In general, regardless of whether the piezoelectric portion 3 is a coating type or not, as a characteristic of a single detection surface of the piezoelectric portion 3, if the direction of strain is locally different, for example, if a compression area A to which the strain is applied and an expansion area B in which the strain is relaxed coexist, electromotive force of one polarity (for example, negative) can be generated in the compression area A, while electromotive force of the other polarity (for example, positive) can be generated in the expansion area B. Accordingly, the electromotive forces of both polarities may be cancelled, causing a decrease in the overall electromotive force of the piezoelectric portion 3. The overall electromotive force can be maximized when the detection surface is occupied by only an area of one polarity. In addition, the overall electromotive force can be minimized when the areas A and B are each present in half. In this case, positive electromotive force and negative electromotive force can be completely canceled, so that the overall electromotive force can become 0. Therefore, when the coating dimensions are set such that coexistence of compression and expansion (in other words, cancellation of positive and negative electromotive forces) is avoided and strain applied to the piezoelectric portion 3 is only compression or expansion, the overall electromotive force can be maximized (amount of power generation can be ensured). This can apply to one or both of the circumferential direction and the width direction of the tire.

Specifically, the length in the width direction of the piezoelectric portion 3 was examined by the inventors through experiments and simulations, and as a result, the length in the width direction of the piezoelectric portion 3 can be in the numerical range of not less than 70% and/or not greater than 150% of a ground-contact width under the maximum load in the standard of the Japan Automobile Tyre Manufacturers Association, Inc. (JATMA). Here, a tire rim, load, internal pressure, etc. are quoted from the standard specified by JATMA, and values thereof are uniquely determined for each type of tire.

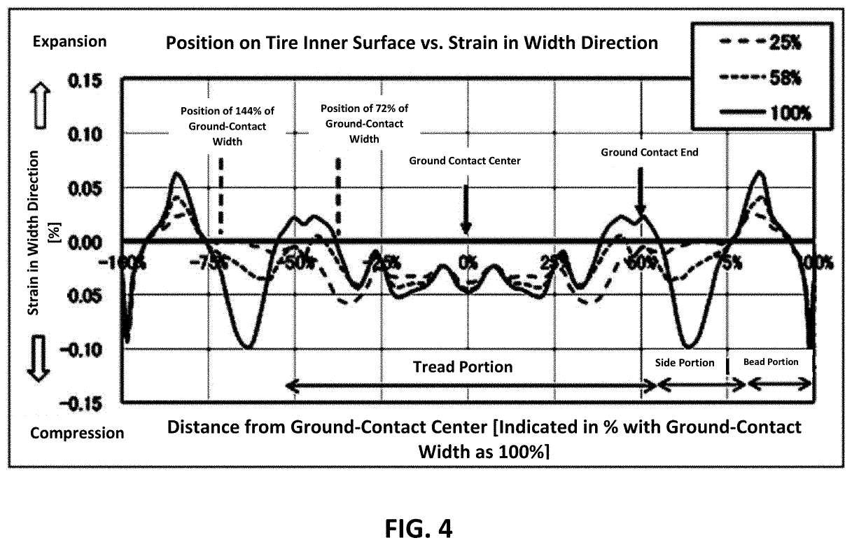

FIG. 4 is a chart obtained by FEM analysis (finite element method analysis) of strain in the width direction in a tire inner surface. In FIG. 4, the horizontal axis indicates the distance from the ground-contact center with a ground-contact width as 100%, in %. Here, the “ground-contact width” can refer to the maximum linear distance in the tire axial direction in the surface of the tire that is in contact with a flat plate when the tire is fitted to an applicable rim, the specified air pressure is applied to the tire, the tire is placed on the flat plate so as to be perpendicular to the flat plate in a stationary state, and a load corresponding to a specified mass is applied to the tire. The air pressure and the load capacity can be specified in advance in this standard. The vertical axis indicates the strain (%) in the width direction, where the positive side corresponds to expansion and the negative side corresponds to compression. The analysis was carried out with the load applied to the tire being 25%, 58%, and 100% of the maximum load in the JATMA standard. As can be seen from FIG. 4, the strain distribution in the width direction can be symmetrical with respect to the ground-contact center (symmetrical on the front side and the back side of the tire).

In the FEM analysis, the strain can be negative from the ground-contact center to the positions of ±36% (72% in total) of the ground-contact width under all the three load conditions. Regardless of the magnitude of the load, the strain can be in the negative region at positions within 70% that is obtained by taking disturbance factors, variations due to size, etc., into consideration for 72%. In addition, from the ground-contact center to the positions of ±72% (144% in total) of the ground-contact width, the strain can be generally in the negative region under the load conditions of 25% and 58%, but a part of the strain can be in the positive region under the load condition of 100%, and the positive and negative strains can be present as a whole. Under a condition of a low load (e.g., under the full-load condition, when the rear tires are braked, etc.), the strain may be only in the negative region at positions within 150% that is obtained by taking disturbance factors, variations due to size, etc., into consideration for 144%.

Meanwhile, the length in the circumferential direction of the piezoelectric portion 3 was examined by the inventors through experiments and simulations, and as a result, the length in the circumferential direction of the piezoelectric portion 3 can be not less than 40% and/or not greater than 90% of the ground-contact length under the maximum load in the JATMA standard.

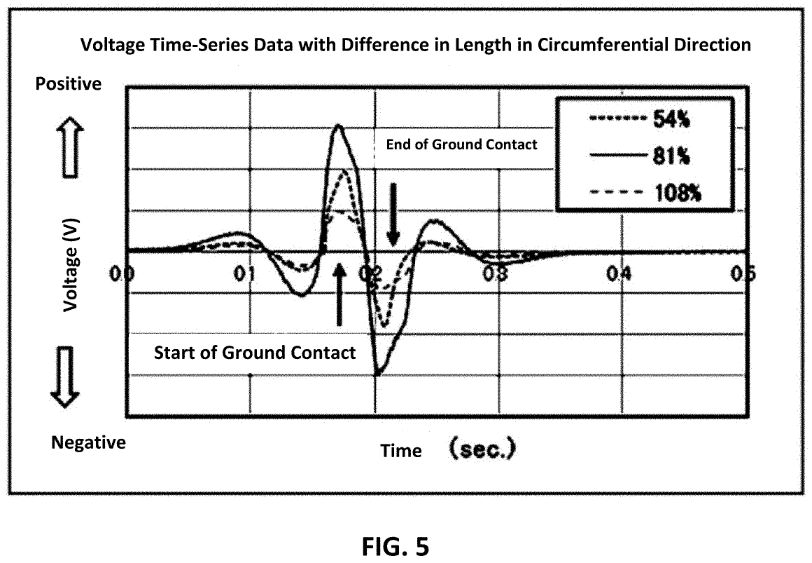

FIG. 5 is a chart showing output voltage data obtained when a load was applied to a tire having the piezoelectric portion 3 coated thereon and the tire was rotated. The horizontal axis indicates time, and the vertical axis indicates an output voltage. Here, the “ground-contact length” can refer to the maximum linear distance in the tire circumferential direction in the surface of the tire that is in contact with a flat plate when the tire is fitted to an applicable rim, the specified air pressure is applied to the tire, the tire is placed on the flat plate so as to be perpendicular to the flat plate in a stationary state, and a load corresponding to a specified mass is applied to the tire. The piezoelectric portions coated in this example respectively can have lengths equal to 54%, 81%, and 108% of the ground-contact length when the ground-contact length is 100%, and the lengths in the width direction thereof are the same. As can be seen from the time-series waveforms of voltage, a voltage can be generated before the piezoelectric portion reaches the ground-contact position and after the piezoelectric portion moves past the ground-contact position. In addition, even if the lengths in the circumferential direction are different, the waveforms may be generally similar.

When the voltage level in FIG. 5 is compared, the voltage level can be the highest for 81% of the ground-contact length, can be second for 54% of the ground-contact length, and can be the lowest for 108% of the ground-contact length. The reason why the piezoelectric portion with 108% can have a low voltage level even though the piezoelectric element amount can be the largest among the three conditions, is that as shown in FIG. 3, an area where strain is compression and an area where strain is expansion can coexist in one piezoelectric element, and positive electromotive force and negative electromotive force can be cancelled, so that the overall electromotive force can be decreased. Therefore, in order to ensure electromagnetic force, the length in the circumferential direction of the piezoelectric portion to be coated can be less than the ground-contact length (i.e., less than 100% of the ground-contact length). Meanwhile, the length in the circumferential direction by which the tire is deformed by applying a load can be the longest at a ground-contact portion on the outermost side, and can be the shortest at a tire inner portion, for instance, due to the thickness of the tread member. In the voltage data in FIG. 5, the voltage level can be the highest for the length in the circumferential direction of 81%, and when the length in the circumferential direction is less than 100% and equal to or less than 90% that is obtained by taking disturbance factors, variations due to size, etc., into consideration for 81%, an area where strain is compression and an area where strain is expansion may not coexist in one piezoelectric element.

Meanwhile, the load during actual running can fluctuate in the range of about 25 to 100%. The ground-contact length under 25% of the maximum load in the JATMA standard can be about 47% of that under 100% of the load, and, in order to prevent positive/negative cancellation within one piezoelectric portion 3 under such a condition, the lower limit can be set to 40%. That is, the lower limit of 40% can be a value that can cover 47% of the ground-contact length under the maximum load, since the ground-contact length can be shortened to 47% of the ground-contact length when the load is low (e.g., under the no-load condition, when the rear tires are braked, etc.).

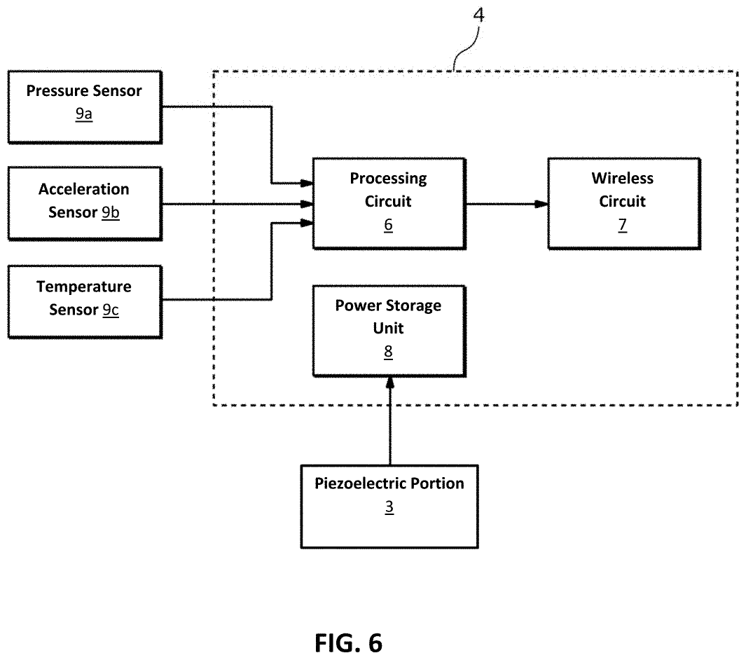

The circuitry 4 can be provided relative to the tire body 2, for instance, on or adjacent to, and cam be driven by the electric power generated by the piezoelectric portion 3. FIG. 6 is a block diagram of the circuitry 4, which may also be referred to herein as a circuit unit 4 or processing circuitry 4. The circuitry 4 can have a function of wirelessly outputting the output of sensors that detect respective states of an object to be detected, to the outside, for instance, outside the tire body 2, the tire, or vehicle on which the tire is mounted, and can include a processing circuit 6, a wireless circuit 7, and a power storage device or unit 8. In the present embodiment, a pressure sensor 9a, an acceleration sensor 9b, and/or a temperature sensor 9c can be provided as the sensors, and can be disposed at appropriate locations such as inside the tire body 2 and on the circuitry 4. The pressure sensor 9a can detect the pressure (air pressure) inside the tire body 2. The acceleration sensor 9b can detect the acceleration of the tire body 2 due to rotation. In addition, the temperature sensor 9c can detect the temperature inside the tire body 2.

The processing circuit 6 can perform signal processing such as AD conversion and noise removal on output signals of the multiple sensors 9a to 9c, and can output the processed signals to the wireless circuit 7. The wireless circuit 7 can wirelessly transmit the processed signals of the sensors 9a to 9c to the outside (for example, a computer inside the vehicle). In addition, the power storage device 8 can include, for instance, a rechargeable battery and can store the electric power generated by the piezoelectric portion 3. Here, the line from the piezoelectric portion 3 to the power storage device 8 can represent one or more leads and lead lines between the piezoelectric portion 3 and the power storage device 8. Then, the stored electric power can be supplied to the processing circuit 6 and the wireless circuit 7 in the circuitry.

As described above, according to the present embodiment, since the coating type can be used as the piezoelectric portion 3 provided on the tire body 2, the piezoelectric portion 3 can be in close contact with the tire body 2, for instance, so that peeling and/or cracking of the electrodes, which may be included in the piezoelectric portion 3, can be suppressed. As a result, the durability of the piezoelectric tire 1A can be improved without impairing the followability to strain of the tire body 2. In this respect, for example, when a piezoelectric element is formed by a method other than coating such as attaching a film, it may be difficult to follow large strain of a tire made of a flexible material, and the electrodes included in the piezoelectric element may be easily peeled off and/or cracked. In addition, when a device-type power generation element is mounted, strain may easily become uneven or the center of gravity may easily deviate. These problems (and other problems) can be effectively solved by using the coating type piezoelectric portion 3 according to embodiments of the disclosed subject matter.

Moreover, according to the present embodiment, when the length in the width direction of the piezoelectric portion 3 is set to be not less than 70% and not greater than 150% of the ground-contact width under the maximum load in the JATMA standard, and/or the length in the circumferential direction of the piezoelectric portion 3 is set to be not less than 40% and not greater than 90% of the ground-contact width under the maximum load in the JATMA standard, it can be possible to effectively ensure an amount of power generation.

In the first embodiment described above, the piezoelectric portion 3 can be used for supplying electric power to the circuitry 4, but can also be used as a sensor for detecting the ground-contact state of the tire body 2 on the basis of a change in output voltage. This point can also apply to a second embodiment described below.

(Second Embodiment)

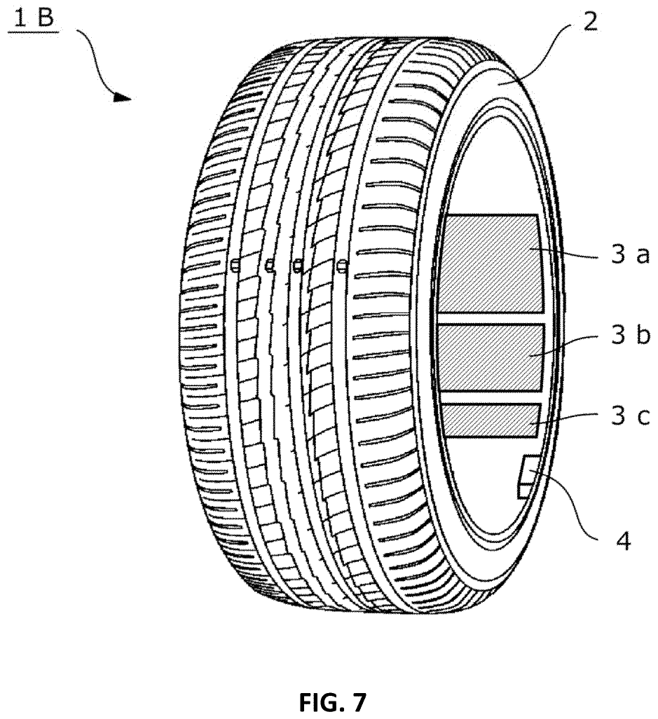

In the second embodiment, a piezoelectric tire in which a plurality of the piezoelectric portions 3 according to the first embodiment are arranged will be described. FIG. 7 is a schematic diagram of the piezoelectric tire according to the second embodiment. The same components as in the first embodiment are designated by the same reference characters, and the description thereof is omitted here.

The piezoelectric tire 1B can include a plurality of piezoelectric portions 3a to 3c provided on the back surface of the ground-contact portion of the tire body 2. These piezoelectric portions 3a to 3c can have a predetermined shape, and individually can generate electric power corresponding to strain generated in the ground-contact surface of the tire body 2. When the plurality of piezoelectric portions 3a to 3c are arranged at intervals, the total amount of power generation (output voltage) can be increased. In the present embodiment, the three piezoelectric portions 3a to 3c can be arranged, but the number of piezoelectric portions arranged is not limited to three. In addition, from the viewpoint of the overall weight balance of the piezoelectric tire 1B, the plurality of piezoelectric portions 3a to 3c may be evenly arranged over the entire circumference of the back surface of the tire body 2.

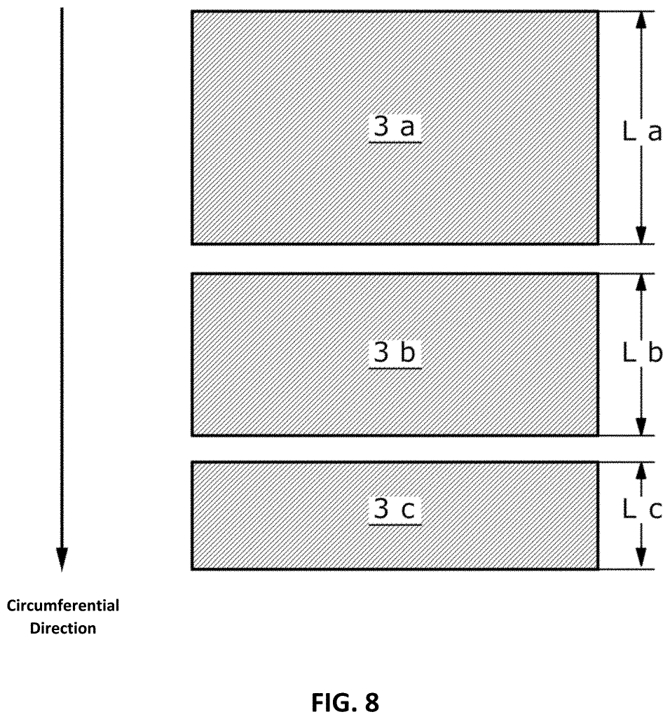

FIG. 8 is an arrangement diagram of the plurality of piezoelectric portions 3a to 3c. The plurality of piezoelectric portions 3a to 3c can be provided at positions different from each other in the circumferential direction of the tire body 2. The piezoelectric portions 3a to 3c can all be based on a rectangular shape and can have a shape obtained by elongating the rectangular shape in the circumferential direction of the tire body 2. That is, the lengths of the piezoelectric portions 3a to 3c in the width direction of the tire body 2 can be the same, but the respective lengths La, Lb, and Lc of the piezoelectric portions 3a to 3c in the circumferential direction of the tire body 2 can be different from each other (La>Lb>Lc).

One purpose of coating the plurality of piezoelectric portions 3a to 3c having different lengths in the circumferential direction can be to ensure an amount of power generation as in the first embodiment described above. The ground-contact length of the tire can be proportional to the load, and in actual running, the load can fluctuate in the range of 25% to 100% of the ground-contact length under the maximum load in the JATMA standard. The compression/expansion of the piezoelectric portions 3a to 3c may also depend on the load. That is, when the lengths in the circumferential direction of the piezoelectric portions 3a to 3c are large and the load is high, only expansion may be caused, so that the electromotive force can be increased. In addition, when the lengths in the circumferential direction of the piezoelectric portions 3a to 3c are large and the load is low, compression and expansion can be caused together, which can result in loss of the electromotive force. On the other hand, when the load is low, a piezoelectric portion having a short length in the circumferential direction can cause only expansion, and thus the electromotive force thereof can be larger than that of a piezoelectric portion having a long length in the circumferential direction. Therefore, when the plurality of piezoelectric portions 3a to 3c having different lengths in the circumferential direction are coated, electromotive force can be effectively ensured even under any load condition.

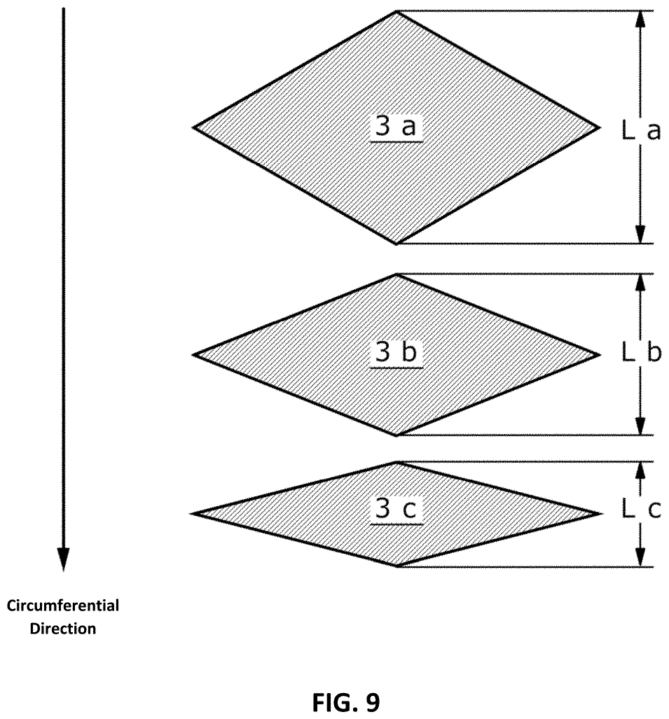

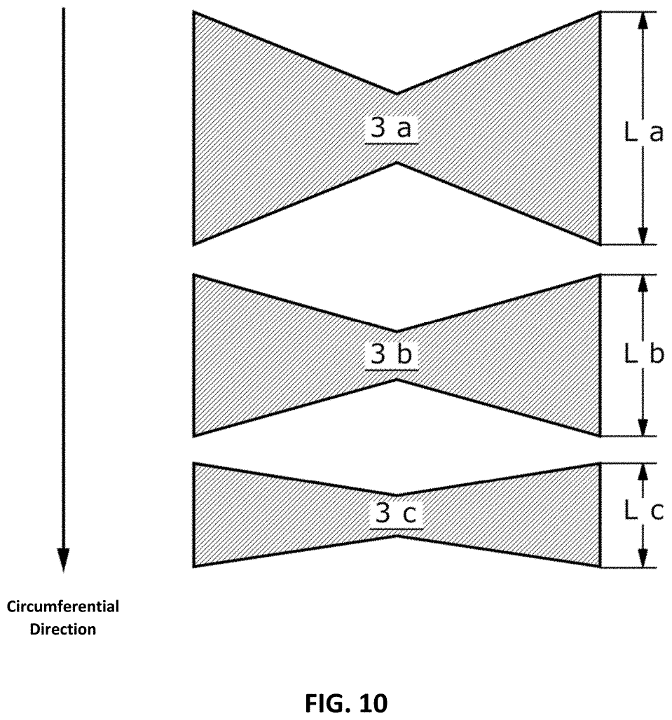

Each of the shapes of the plurality of piezoelectric portions 3a to 3c is not limited to a rectangular shape, and an appropriate shape can be adopted in consideration of the strain shape of the tire body 2 in a ground-contact state. For example, as shown in FIG. 9, a rhombus shape may be used as a base, and the shape of each of the piezoelectric portions 3a to 3c may be a shape obtained by elongating the rhombus shape in the circumferential direction of the tire body 2. Moreover, as shown in FIG. 10, a shape obtained by line-symmetrically arranging two trapezoids may be used as a base, and the shape of each of the piezoelectric portions 3a to 3c may be a shape obtained by elongating this shape in the circumferential direction of the tire body 2.

As described above, according to the present embodiment, since the plurality of piezoelectric portions 3a to 3c having different lengths in the circumferential direction of the tire body 2 can be provided, an amount of power generation can be effectively ensured even under any load condition.

In the second embodiment, the example focusing on the circumferential direction of the tire body 2 has been described above, but instead, a plurality of piezoelectric portions may be provided at different positions in the width direction of the tire body 2, or may be provided in both the circumferential direction and the width direction of the tire body 2. In this case, the plurality of piezoelectric portions provided in the width direction may have a shape elongated in the width direction of the tire body 2 as in the case of the circumferential direction.

Furthermore, embodiments of the present disclosure can be regarded not only in terms of a piezoelectric tire (or portions thereof), but also as a method for producing a piezoelectric tire (or portions thereof), such as forming the piezoelectric portions 3 and 3a to 3c by coating on the tire body 2.

What is claimed is:

1. A piezoelectric tire comprising:
a tire body;
a coating piezoelectric portion coated on the tire body to generate electric power corresponding to strain generated in a ground-contact surface of the tire body; and
circuitry provided to the tire body and configured to be driven by the electric power generated by the coating type piezoelectric portion.

2. The piezoelectric tire according to claim 1, wherein the coating piezoelectric portion is coated on a back surface of a ground-contact portion of the tire body.

3. The piezoelectric tire according to claim 2, further comprising a resin layer interposed between the coating piezoelectric portion and the tire body such that the coating piezoelectric portion is not in direct contact with the tire body.

4. The piezoelectric tire according to claim 1, wherein a length in a width direction of the coating piezoelectric portion is not less than 70% and not greater than 150% of a ground-contact width under a maximum load in a standard of Japan Automobile Tyre Manufacturers Association, Inc.

5. The piezoelectric tire according to claim 1, wherein a length in a circumferential direction of the coating piezoelectric portion is not less than 40% and not greater than 90% of a ground-contact length under a maximum load in a standard of Japan Automobile Tyre Manufacturers Association, Inc.

6. The piezoelectric tire according to claim 1, wherein a plurality of the coating piezoelectric portions are provided at different positions in at least either one of a circumferential direction and a width direction of the tire body.

7. The piezoelectric tire according to claim 6, wherein the plurality of the coating piezoelectric portions have lengths different from each other in the circumferential direction of the tire body.

8. The piezoelectric tire according to claim 6, wherein the plurality of the coating piezoelectric portions have lengths different from each other in the width direction of the tire body.

9. The piezoelectric tire according to claim 7, wherein the plurality of the coating piezoelectric portions each have a shape obtained by elongating a predetermined shape in the circumferential direction of the tire body.

10. The piezoelectric tire according to claim 1, wherein the circuitry includes a wireless circuit configured to wirelessly transmit a signal of a sensor configured to detect a state of an object to be detected, to outside the piezoelectric tire.

11. The piezoelectric tire according to claim 1, wherein the circuitry includes a power storage device configured to store the electric power generated by the coating piezoelectric portion and supply the stored electric power to the circuitry.

12. A tire system comprising:
a coating piezoelectric portion coated on a tire body to generate electric power corresponding to strain generated in a ground-contact surface of the tire body; and
circuitry provided relative to the tire body and configured to be driven by the electric power generated by the coating type piezoelectric portion,
wherein the coating piezoelectric portion is coated on a back surface of a ground-contact portion of the tire body.

13. The tire system according to claim 12, further comprising a resin layer interposed between the coating piezoelectric portion and the tire body such that the coating piezoelectric portion is not in direct contact with the tire body.

14. The tire system according to claim 12, wherein a length in a width direction of the coating piezoelectric portion is not less than 70% and not greater than 150% of a ground-contact width under a maximum load in a standard of Japan Automobile Tyre Manufacturers Association, Inc.

15. The tire system according to claim 12, wherein a length in a circumferential direction of the coating piezoelectric portion is not less than 40% and not greater than 90% of a ground-contact length under a maximum load in a standard of Japan Automobile Tyre Manufacturers Association, Inc.

16. The tire system according to claim 12, wherein a plurality of the coating piezoelectric portions are coated on the back surface at different positions in at least either one of a circumferential direction and a width direction of the tire body.

17. The tire system according to claim 16, wherein the plurality of the coating piezoelectric portions have lengths different from each other in the circumferential direction of the tire body.

18. The tire system according to claim 16, wherein the plurality of the coating piezoelectric portions have lengths different from each other in the width direction of the tire body.

19. The tire system according to claim 12, wherein the circuitry includes a wireless circuit configured to wirelessly transmit a signal of a sensor configured to detect a state of a tire to outside the piezoelectric tire.

20. The tire system according to claim 12, wherein the circuitry includes a power storage device configured to store the electric power generated by the coating piezoelectric portion and supply the stored electric power to the circuitry.
